(19) United States
(12) Patent Application Publication
(10) Pub. No.: US 2016/0069999 A1
(43) Pub. Date: Mar. 10, 2016

(54) DEPTH IMAGE OBTAINING DEVICE AND DISPLAY DEVICE USING SAME

(71) Applicant: LG ELECTRONICS INC., Seoul (KR)

(72) Inventors: Manhyung LEE, Seoul (KR); Youngman KWON, Seoul (KR); Sungmin KIM, Seoul (KR); Jinwon KANG, Seoul (KR); Sunho YANG, Seoul (KR)

(73) Assignee: LG ELECTRONICS INC., Seoul (KR)

(21) Appl. No.: 14/778,002

(22) PCT Filed: Mar. 5, 2014
(86) PCT No.: PCT/KR2014/001811

§ 371 Date: Sep. 17, 2015

Related U.S. Application Data
(60) Provisional application No. 61/805,109, filed on Mar. 25, 2013.
(60) Provisional application No. 61/811,811, filed on Apr. 15, 2013.

(51) Int. Cl. G01S 17/89; H01S 5/183; G01S 17/08; F21V 29/70; F21V 9/00; H04N 13/02; F21V 7/06

(52) U.S. Cl. CPC G01S 17/89; H04N 13/02; H01S 5/183; F21V 7/06; F21V 29/70; F21V 9/00; G01S 17/08

(57) ABSTRACT

The present invention relates to a depth image obtaining device enabled to obtain a depth image of a subject located at a far distance, and a display device using the same, the depth image obtaining device comprising: a light irradiation part for irradiating light onto a predetermined subject; a light receiving part receiving light reflected from the subject; and a control part for controlling the light irradiation part and the light receiving part. The light irradiation part comprises alight source part for emitting light in a first direction and a reflection part for reflecting the light emitted in the first direction into a second direction.

### FIELD OF THE INVENTION

The present invention relates to a depth image obtaining device and, more particularly, to a depth image obtaining device enabled to obtain a depth image of a subject located at a far distance and a display device using the same.

### BACKGROUND ART

Generally, 3-dimensional (3D) information includes geometry information and color information, and geometry information may be obtained by using depth information.

For such depth information, there is a method of directly obtaining the depth information by using hardware equipment, such as a depth camera, and a method of indirectly obtaining the depth information by an image processing via software, which is referred to as a computer vision technology.

Meanwhile, the depth camera is mainly used in a method for obtaining depth images by using ToF (Time of Flight).

Herein, the method using ToF (Time of Flight), which corresponds to a method of measuring a time length for a light ray being irradiated onto a subject to return after being reflected from the subject, includes a direct method for sensing (or detecting) ToF by sensing a moment when a reflected light ray returns to a light receiving part by using a special sensor that is sensitive to light, and an indirect method of performing calculation after detecting phase differences of pulse light rays as an amount of electric charge, when pulse light rays that are modulated by using a photo diode return after being reflected.

However, in case the subject is located at a remote (or far) distance, since the amount of light that returns after being reflected from the subject is small, when using a depth camera using the above-described method, accuracy in the obtained depth image may become degraded.

Accordingly, in order to accurately obtain a depth image of a subject, which is located at a remote distance, a light source having a high power level may be required to be used, or a number of light sources may be required to be increased.

However, in case of using a light source having a high power level, or in case of increasing the number of light sources, since eye-safety problems may occur, the light source shall be positioned in a way to ensure safety distance of equipments.

Such safety distance of equipments becomes a factor of increasing thickness and size of lighting modules respective to depth cameras.

### DETAILED DESCRIPTION OF THE INVENTION

### Technical Objects

A technical object that is to be achieved by the present invention is to provide a depth image obtaining device, which is places a reflection part in a light irradiation part, and which can resolve the eye-safety problem without increasing the thickness and size of the lighting module, and which can accurately obtain a depth image respective to the user being positioned at a remote location (or a far distance), and a display device using the same.

### Technical Solutions

In order to achieve the above-described technical object, a depth image obtaining device according to the present invention may include a light irradiation part for irradiating light onto a predetermined subject, a light receiving part for receiving light reflected from the subject, and a control part for controlling the light irradiation part and the light receiving part, wherein the light irradiation part may include a light source part for emitting light in a first direction, and a reflection part for reflecting the light emitted in the first direction into a second direction.

Herein, a central axis of the light being emitted in the first direction and a central axis of the light being reflected along the second direction may be perpendicular to one another.

Additionally, the light source part may correspond to at least one of a laser diode and a VCSEL (Vertical Cavity Surface Emitting Laser).

Moreover, the reflection part may correspond to a parabolic front coated mirror.

And, the light source part and the reflection part may be positioned on a same substrate, and the light source part and the reflection part may be serially aligned.

Subsequently, the light irradiation part may further include an optical member positioned between the light source part and the reflection part for providing the light emitted from the light source part as a collimated light.

Additionally, the light irradiation part and the light receiving part may be configured as an integrated module by being positioned on a same substrate.

Herein, the integrated module including the light irradiation part and the light receiving part may be mounted on a display device, and the integrated module may be exposed outside from the display device.

In some cases, the light irradiation part may be positioned on a first substrate so as to be configured as a first detachable module, and the light receiving part may be positioned on a second substrate so as to be configured as a second detachable module.

Herein, the first detachable module including the light irradiation part and the second detachable module including the light receiving part may be mounted on a display device, and the first detachable module may be positioned inside the display device, and the second detachable module may be exposed outside from the display device.

At this point, the first detachable module may be positioned behind a display panel of the display device.

Meanwhile, a display device using a depth image obtaining device according to the present invention may include a display panel, a backlight unit for emitting light onto the display panel, a light irradiation part positioned inside the backlight unit for irradiating light onto a predetermined subject, a light receiving part positioned on a peripheral portion of the display panel for receiving light reflected from the subject, and a control part for controlling the light irradiation part and the light receiving part, wherein the light irradiation part may include a light source part for emitting light in a first direction, and a reflection part for reflecting the light emitted in the first direction into a second direction.

Herein, the backlight unit may include a light source module including a substrate and multiple light sources being positioned on the substrate, a dispersion plate positioned over the light source module, and an optical member positioned over the dispersion plate, wherein the light irradiation part may be positioned in at least any one of a location inside the light source module, a location between the light source module and the dispersion plate, and a location between the dispersion plate and the optical member.

At this point, the light irradiation part may be positioned between light sources of the light source module.

And, the light irradiation part and the light source may be positioned on a same substrate.

Thereafter, a heat radiation plate may be positioned under the substrate of the light source module.

And, the light irradiation part may be positioned on one side next to the light source module, so as to be spaced apart from the light source module at a predetermined distance.

Additionally, a color cut filter may be positioned over the light irradiation part.

Furthermore, the light irradiation part may be positioned as multiple separate modules, or the light irradiation part may be positioned as multiple group modules including multiple separate modules, wherein the multiple separate modules may be positioned to be spaced apart from the light receiving part at equal distances, and wherein the multiple separate groups may be positioned to be spaced apart from the light receiving part at equal distances.

Subsequently, the light irradiation part may be positioned on a peripheral portion of the display panel so as to be adjacent to the light receiving part.

### Effects of the Invention

According to the depth image obtaining device and the display device using the same according to the present invention, the present invention is advantageous in that the eye-safety problem may be resolved without increasing the thickness and size of the lighting module, thereby being capable of accurately obtaining a depth image respective to the user being positioned at a remote location.

The additional scope of applicability of the present invention will become apparent based upon the detailed description of the present invention, which will be provided in the following description. However, since diverse variations and modifications of the present invention, which are realized without departing from the scope and spirit of the present invention, may be clearly understood by anyone skilled in the art, it should be understood that the specific exemplary embodiments of the present invention, such as the detailed description of the present invention and the preferred embodiments of the present invention, are merely given as an example of the present invention.

### BRIEF DESCRIPTION OF THE DRAWINGS

FIG. 1 illustrates a block view showing a structure of a depth image obtaining device according to the present invention,

FIG. 2 illustrates a lateral view showing a light irradiation part according to a first exemplary embodiment of the present invention,

FIG. 3 illustrates a lateral view showing a light irradiation part according to a second exemplary embodiment of the present invention,

FIG. 4a and FIG. 4b illustrate plane views respectively showing arrays of light irradiation parts according to FIG. 2,

FIG. 5a and FIG. 5b illustrate plane views respectively showing arrays of light irradiation parts according to FIG. 3,

FIG. 6a and FIG. 6b illustrate plane views respectively showing positioning of a light irradiation part and a light receiving part,

FIG. 7a and FIG. 7b respectively illustrate a depth image obtaining device being equipped to a display device,

FIG. 8 illustrates a depth image obtaining device being applied to a display device having a large screen,

FIG. 9a to FIG. 9d respectively illustrate exploded views showing a display device using the depth image obtaining device according to the present invention,

FIG. 10 illustrates a positioning of a light irradiation part being applied to a backlight unit of the display device according to the present invention,

FIG. 11a and FIG. 11b illustrate cross-sectional views taken along line I-I of FIG. 10,

FIG. 12 illustrates a block view showing a structure of a control part controlling the backlight unit of the display device according to the present invention,

FIG. 13a and FIG. 13b respectively illustrate alignments of the light irradiation part being positioned in the backlight unit of the display device according to the present invention,

FIG. 14a and FIG. 14b respectively illustrate alignments of the light irradiation part being positioned in a frame of a display device.

### BEST MODE FOR CARRYING OUT THE PRESENT INVENTION

Reference will now be made in detail to the preferred embodiments of the present invention, examples of which are illustrated in the accompanying drawings. Wherever possible, the same reference numbers will be used throughout the drawings to refer to the same or like parts, and repeated description will be omitted for simplicity. The suffixes “module” and “unit” that are mentioned in the elements used to describe the present invention are merely used for the purpose of simplifying the description of the present invention. Therefore, the suffixes “module” and “unit” may also be alternately used for the reference of a specific element of the present invention. Each of the suffixes will not be signified or used to differential one from the other. Additionally, in describing exemplary embodiments, which are disclosed in this specification, when it is determined that detailed description of related technologies, which have already been disclosed, may cause ambiguity in the concept of the exemplary embodiments disclosed in this specification, the detailed description of the same will be omitted for simplicity. Additionally, the accompanying drawings are merely provided to facilitate the understanding the exemplary embodiments disclosed in this specification. And, therefore, the technical scope and spirit disclosed in this specification will not be limited only to the accompanying drawings. And, therefore, it should be understood that the accompanying drawings include all variations, equivalents and replacements that are included in the technical scope and spirit of the present invention.

Terms including ordinal numbers, such as “first”, “second”, and so on, may be used for describing diverse elements. However, such elements will not be limited only to such terms. Herein, the corresponding terms will only be used to differentiate one element from another element.

When an element is said (or described) to be “connected to” or “in connection with” another element, the corresponding element may be directly connected to or may be in direct connection with the other element. However, it should be understood that yet another element may exist in-between. Conversely, when an element is said (or described) to be “directly connected to” or “in direct connection with” another element, it should also be understood that no other element exists between the two elements.

Additionally, unless clearly mentioned otherwise within the context, singular form expressions shall include the respective plural form expressions.

In this application, the terms “include(s)” or “have (or has)” are merely used to indicate the presence of a characteristic, number, step, operation, element, assembly part, or a combination of at least two or more of the above, which are mentioned in the description of the present invention. And, therefore, it should be understood that the presence or possibility of additionally including one or more of other characteristics, numbers, steps, operations, elements, assembly parts, or combinations of the above will not be excluded in advance.

It will be apparent to anyone skilled in the art that the structure according to the exemplary embodiment described in this specification may not only be applied to fixed terminals (or user equipments), such as digital TVs, desktop computers, digital signage, and so on, but may also be applied to mobile terminals (or user equipments).

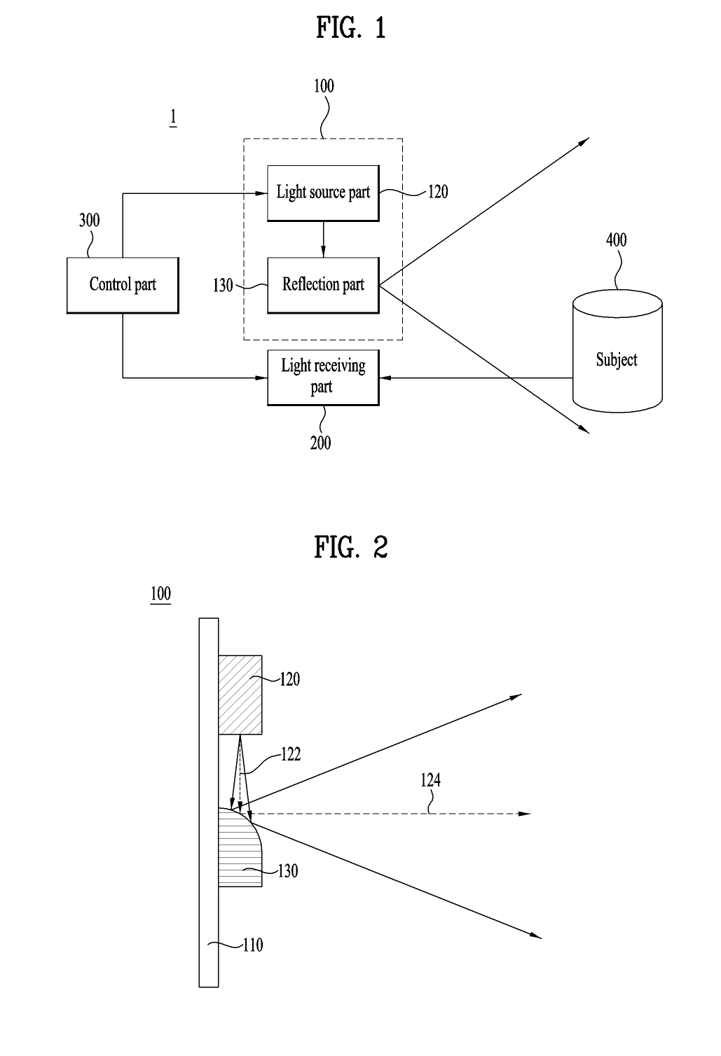

FIG. 1 illustrates a block view showing a structure of a depth image obtaining device according to the present invention.

As shown in FIG. 1, the depth image obtaining device (1) may include a light irradiation part (100), a light receiving part (200), and a control part (300).

Herein, the light irradiation part (100) may irradiate light onto a predetermined subject (400), and the light irradiation part (100) may include a light source part (120) and a reflection part (130).

At this point, the light source part (120) may emit light in a first direction, and the reflection part (130) may reflect the light emitted in the first direction into a second direction.

For example, although a central axis of a light being emitted in a first direction and a central axis of a light being reflected along a second direction may be perpendicular to one another, the present invention will not be limited only to this.

Additionally, the light source part (120) may correspond to at least one of a laser diode and a VCSEL (Vertical Cavity Surface Emitting Laser).

For example, the light source part (120) may correspond to a laser light source having a high output of approximately 100 mW or more.

Additionally, the reflection part (130) may correspond to a front coated mirror having a predetermined curvature, and, for example, the reflection part (130) may correspond to a parabolic front coated mirror.

Herein, the reflection part (130) may have a curvature on only a part of its surface, or the reflection part (130) may have a curvature on its entire surface.

At this point, in the reflection part (130), the surface having the curvature may be positioned to face into a light emitting surface of the light source part (120).

Additionally, since a curvature value of the surface of the reflection part (130) performs a function of determining a dispersion angle of light being reflected from the reflection part (130), the curvature value may be determined (or decided) based upon a distance between the reflection part (130) and the subject (400) and based upon a light output of the light source.

Subsequently, the light source part (120) and the reflection part (130) may be positioned on a same substrate and may be serially aligned along a same line.

For example, the reflection part (130) may be positioned along a light emitting direction of the light source part (120).

Herein, although there may be only one light irradiation part (100) including the light source part (120) and the reflection part (130), in some cases, there may be a plurality of light irradiation parts.

In some cases, an optical member providing light, which is being emitted from the light source part (120), as collimated light may be positioned between the light source part (120) and the reflection part (130).

Herein, the light source part (120), the optical member, and the reflection part (130) may be positioned on a same substrate and may be serially aligned along a same line.

For example, the optical member and the reflection part (130) may be serially positioned along a light emitting direction of the light source part (120).

In some cases, a first distance between the light source part (120) and the optical member and a second distance between the optical member and the reflection part (130) may be different from one another.

For example, a first distance between the light source part (120) and the optical member may be shorter (or smaller) than a second distance between the optical member and the reflection part (130).

In another case, a first distance between the light source part (120) and the optical member and a second distance between the optical member and the reflection part (130) may be identical to one another.

Herein, although there may be only one light irradiation part (100) including the light source part (120), the optical member, and the reflection part (130), in some cases, there may be a plurality of light irradiation parts.

And, the light irradiation part (100) and the light receiving part (200) may be positioned on the same substrate, so as to be configured as an integrated module.

In some cases, the light irradiation part (100) may also be positioned on a first substrate, so as to be configured as a first detachable module, and the light receiving part (200) may also be positioned on a second substrate, so as to be configured as a second detachable module.

Subsequently, the light receiving part (200) may receive the light being reflected from the subject (400).

Herein, the light receiving part (200) may be positioned on a same substrate as the light irradiation part (100), so as to be configured as a single module.

In some cases, the light receiving part (200) may be positioned on a substrate that is different from that of the light irradiation part (100), so as to be configured as separate modules each being different from one another.

Additionally, although it is not shown in the drawings, the depth image obtaining device may extract depth image information from the light that is received by the light receiving part (200).

Subsequently, the control part (300) may control the light irradiation part (100) and the light receiving part (200), and, herein, the control part (300) may control the light irradiation part (100) and the light receiving part (200) simultaneously, and, in some cases, the control part (300) may control the light irradiation part (100) and the light receiving part (200) at different time points.

As described above, in case the light irradiation part (100) uses a high output light source, since a safety distance is required to be ensured due to the eye-safety problem, the overall thickness of the depth image obtaining device was likely to become significantly large, however, as described in the present invention, by serially positioning the reflection part (130) on a light emitting surface of the light source part (120), the thickness of the depth image obtaining device may be reduced as much as the distance between the light source part (120) and the reflection part (130).

Accordingly, in the present invention, since a low output light source may be replaced with a high output light source without having to increase the thickness and size of the depth image obtaining device using a low output light source, the depth image obtaining device may become more compact in size, and a depth image respective to the subject (400), which is positioned at a remote location, may be accurately obtained as well.

FIG. 2 illustrates a lateral view showing a light irradiation part according to a first exemplary embodiment of the present invention.

As shown in FIG. 2, the light irradiation part (100) may include a substrate (110), and a light source part (120) and a reflection part (130) being positioned on the substrate (110).

Herein, the light source part (120) and the reflection part (130) may be serially positioned on the same substrate (110).

For example, the reflection part (130) may be positioned along a light emitting direction of the light source part (120).

At this point, the light source part (120) may emit light in a first direction, and the reflection part (130) may reflect the light emitted in the first direction into a second direction.

For example, although a central axis (122) of a light being emitted in a first direction and a central axis (124) of a light being reflected along a second direction may be perpendicular to one another, the present invention will not be limited only to this.

In some cases, an angle formed between a central axis (122) of a light being emitted in a first direction and a central axis (124) of a light being reflected along a second direction may be an obtuse angle or an acute angle.

Herein, the angle formed between the central axis (122) of the light being emitted in the first direction and the central axis (124) of the light being reflected along the second direction may vary depending upon a curvature of a surface of the reflection part (130).

Moreover, a distance between the light source part (120) and the reflection part (130) may be determined (or decided) based upon a safety distance respective to the eye-safety.

Subsequently, the light source part (120) may correspond to at least one of a laser diode and a VCSEL (Vertical Cavity Surface Emitting Laser).

For example, the light source part (120) may correspond to a laser light source having a high output of approximately 100 mW or more.

Additionally, the reflection part (130) may correspond to a front coated mirror having a predetermined curvature, and, for example, the reflection part (130) may correspond to a parabolic front coated mirror.

Herein, the reflection part (130) may have a curvature on only a part of its surface, or the reflection part (130) may have a curvature on its entire surface,

At this point, in the reflection part (130), the surface having the curvature may be positioned to face into a light emitting surface of the light source part (120).

Additionally, since a curvature value of the surface of the reflection part (130) performs a function of determining a dispersion angle of light being reflected from the reflection part (130), the curvature value may be determined (or decided) based upon a distance between the reflection part (130) and the subject (400) and based upon a light output of the light source.

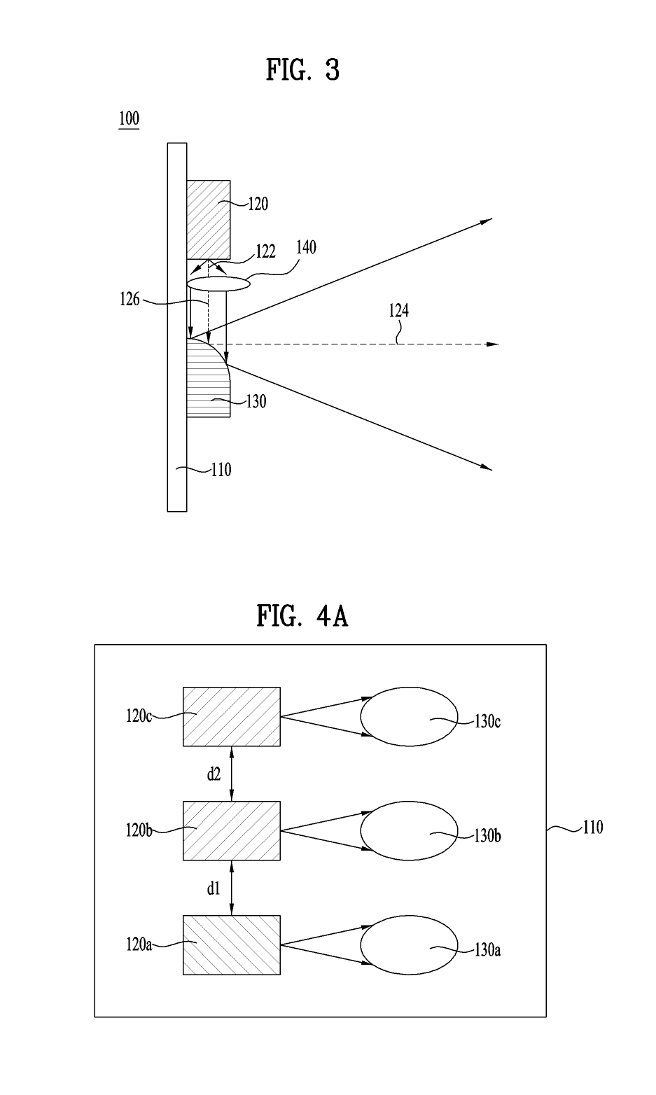

FIG. 3 illustrates a lateral view showing a light irradiation part according to a second exemplary embodiment of the present invention.

As shown in FIG. 3, the light irradiation part (100) may include a substrate (110), and a light source part (120), an optical member (140), and a reflection part (130) being positioned on the substrate (110).

Herein, the light source part (120), the optical member (140), and the reflection part (130) may be serially positioned on the same substrate (110).

For example, the optical member (140) may be positioned between the light source part (120) and the reflection part (130) and may be positioned along a light emitting direction of the light source part (120).

At this point, the light source part (120) may emit light in a first direction, and the optical member (140) may convert the light to collimated light and emit the converted light in the first direction, and the reflection part (130) may reflect the collimated light, which is emitted in the first direction from the optical member (140), in a second direction.

For example, a central axis (122) of the light being emitted from the light source part (120) and a central axis (126) of the light being emitted from the optical member (140) may be identical to one another.

In some cases, an angle formed between a central axis (122) of the light being emitted from the light source part (120) and a central axis (126) of the light being emitted from the optical member (140) may be an obtuse angle.

Additionally, although a central axis (126) of a light being emitted from the optical member (140) and a central axis (124) of a light being reflected from the reflection part (130) may be perpendicular to one another, the present invention will not be limited only to this.

In some cases, an angle formed between a central axis (126) of a light being emitted from the optical member (140) and a central axis (124) of a light being reflected from the reflection part (130) may be an obtuse angle or an acute angle.

Herein, the angle formed between the central axis (126) of the light being emitted from the optical member (140) and the central axis (124) of the light being reflected from the reflection part (130) may vary depending upon a curvature of a surface of the reflection part (130).

Moreover, a distance between the light source part (120) and the reflection part (130) may be determined (or decided) based upon a safety distance respective to the eye-safety.

In some cases, a first distance between the light source part (120) and the optical member (140) and a second distance between the optical member (140) and the reflection part (130) may be different from one another.

For example, a first distance between the light source part (120) and the optical member (140) may be shorter (or smaller) than a second distance between the optical member (140) and the reflection part (130).

In another case, a first distance between the light source part (120) and the optical member (140) and a second distance between the optical member (140) and the reflection part (130) may be identical to one another.

Subsequently, the light source part (120) may correspond to at least one of a laser diode and a VCSEL (Vertical Cavity Surface Emitting Laser).

For example, the light source part (120) may correspond to a laser light source having a high output of approximately 100 mW or more.

Additionally, the reflection part (130) may correspond to a front coated mirror having a predetermined curvature, and, for example, the reflection part (130) may correspond to a parabolic front coated mirror.

Herein, the reflection part (130) may have a curvature on only a part of its surface, or the reflection part (130) may have a curvature on its entire surface,

Subsequently, the optical member (140) may correspond to a collimating lens, which converts light to collimated light.

At this point, the optical member (140) may be positioned to face into a light emitting surface of the light source part (120).

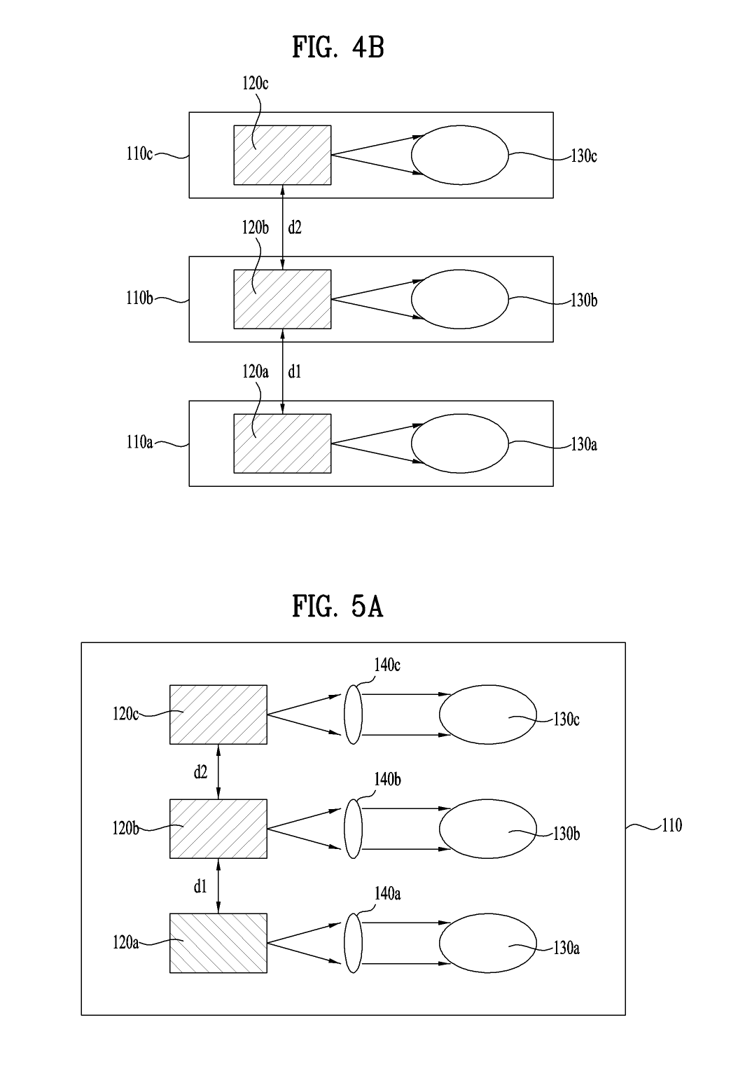

FIG. 4a and FIG. 4b illustrate plane views respectively showing arrays of light irradiation parts according to FIG. 2, wherein FIG. 4a corresponds to an integrated module, and wherein FIG. 4b corresponds to a detachable module.

Herein, as shown in FIG. 4a and FIG. 4b, although there may be only one light irradiation part (100) including the light source part (120) and the reflection part (130), in some cases, there may be a plurality of light irradiation parts.

As shown in FIG. 4a, multiple light source parts (120) and multiple reflection parts (130) may be positioned on a single substrate (110).

For example, the light source part (120) may include first, second, and third light source parts (120a, 120b, 120c), and the reflection part (130) may include first, second, and third reflection parts (130a, 130b, 130c).

Herein, the first reflection part (130a) may be positioned along a light emitting direction of the first light source part (120a), and the second reflection part (130b) may be positioned along a light emitting direction of the second light source part (120b), and the third reflection part (130c) may be positioned along a light emitting direction of the third light source part (120c).

Additionally, the first light source part (120a) and the second light source part (120b) are positioned to be spaced apart from one another so as to have a first distance d1, and the second light source part (120b) and the third light source part (120c) are positioned to be spaced apart from one another so as to have a second distance d2.

Herein, the first distance d1 and the second distance d2 may be identical to one another or, in some cases, may be different from one another.

At this point, the first distance d1 and the second distance d2 may be controlled so that light rays being emitted from neighboring light source parts (120) do not overlap with one another.

Additionally, as shown in FIG. 4b, each set of a light source part (120) and a reflection part (130) may be positioned on each of multiple substrates (110).

For example, a first light irradiation part is configured of a first light source part (120a) and a first reflection part (130a) being positioned on a first substrate (110a), and a second light irradiation part is configured of a second light source part (120b) and a second reflection part (130b) being positioned on a second substrate (110b), and a third light irradiation part is configured of a third light source part (120c) and a third reflection part (130c) being positioned on a third substrate (110c).

Herein, the first reflection part (130a) may be positioned along a light emitting direction of the first light source part (120a), and the second reflection part (130b) may be positioned along a light emitting direction of the second light source part (120b), and the third reflection part (130c) may be positioned along a light emitting direction of the third light source part (120c).

Additionally, each of the first, second, and third substrates (110a, 110b, 110c) may be positioned to be spaced apart from one another at a predetermined distance.

Moreover, the first light source part (120a) and the second light source part (120b) are positioned to be spaced apart from one another so as to have a first distance d1, and the second light source part (120b) and the third light source part (120c) are positioned to be spaced apart from one another so as to have a second distance d2.

Herein, the first distance d1 and the second distance d2 may be identical to one another or, in some cases, may be different from one another.

At this point, the first distance d1 and the second distance d2 may be controlled so that light rays being emitted from neighboring light source parts (120) do not overlap with one another.

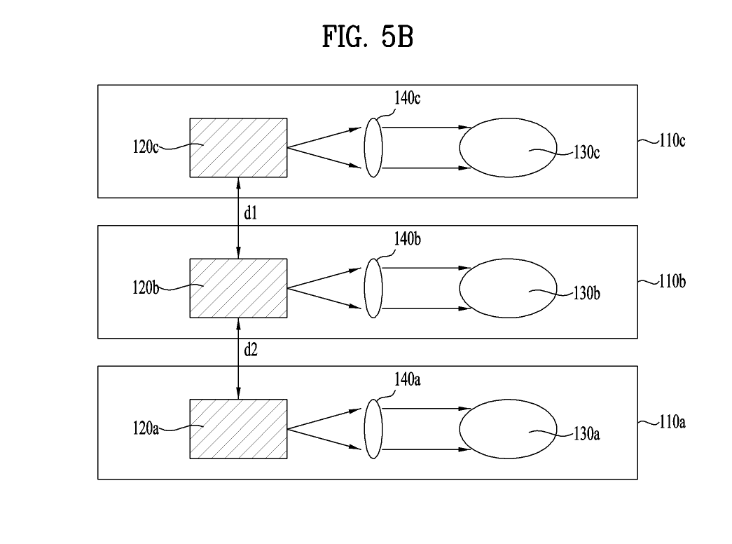

FIG. 5a and FIG. 5b illustrate plane views respectively showing arrays of light irradiation parts according to FIG. 3, wherein FIG. 5a corresponds to an integrated module, and wherein FIG. 5b corresponds to a detachable module.

Herein, as shown in FIG. 5a and FIG. 5b, although there may be only one light irradiation part (100) including the light source part (120) and the reflection part (130), in some cases, there may be a plurality of light irradiation parts.

As shown in FIG. 5a, multiple light source parts (120) and multiple reflection parts (130) and multiple optical members (140) may be positioned on a single substrate (110).

For example, the light source part (120) may include first, second, and third light source parts (120a, 120b, 120c), and the reflection part (130) may include first, second, and third reflection parts (130a, 130b, 130c), and the optical member (140) may include first, second, and third optical members (140a, 140b, 140c).

Herein, the first reflection part (130a) and the first optical member (140a) may be positioned along a light emitting direction of the first light source part (120a), and the second reflection part (130b) and the second optical member (140b) may be positioned along a light emitting direction of the second light source part (120b), and the third reflection part (130c) and the third optical member (140c) may be positioned along a light emitting direction of the third light source part (120c).

Additionally, the first light source part (120a) and the second light source part (120b) are positioned to be spaced apart from one another so as to have a first distance d1, and the second light source part (120b) and the third light source part (120c) are positioned to be spaced apart from one another so as to have a second distance d2.

Herein, the first distance d1 and the second distance d2 may be identical to one another or, in some cases, may be different from one another.

At this point, the first distance d1 and the second distance d2 may be controlled so that light rays being emitted from neighboring light source parts (120) do not overlap with one another.

Additionally, as shown in FIG. 5b, each set of a light source part (120) and a reflection part (130) and an optical member (140) may be positioned on each of multiple substrates (110).

For example, a first light irradiation part is configured of a first light source part (120a) and a first reflection part (130a) and a first optical member (140a) being positioned on a first substrate (110a), and a second light irradiation part is configured of a second light source part (120b) and a second reflection part (130b) and a second optical member (140b) being positioned on a second substrate (110b), and a third light irradiation part is configured of a third light source part (120c) and a third reflection part (130c) and a third optical member (140c) being positioned on a third substrate (110c).

Herein, the first reflection part (130a) and the first optical member (140a) may be positioned along a light emitting direction of the first light source part (120a), and the second reflection part (130b) and the second optical member (140b) may be positioned along a light emitting direction of the second light source part (120b), and the third reflection part (130c) and the third optical member (140c) may be positioned along a light emitting direction of the third light source part (120c).

Additionally, each of the first, second, and third substrates (110a, 110b, 110c) may be positioned to be spaced apart from one another at a predetermined distance.

Moreover, the first light source part (120a) and the second light source part (120b) are positioned to be spaced apart from one another so as to have a first distance d1, and the second light source part (120b) and the third light source part (120c) are positioned to be spaced apart from one another so as to have a second distance d2.

Herein, the first distance d1 and the second distance d2 may be identical to one another or, in some cases, may be different from one another.

At this point, the first distance d1 and the second distance d2 may be controlled so that light rays being emitted from neighboring light source parts (120) do not overlap with one another.

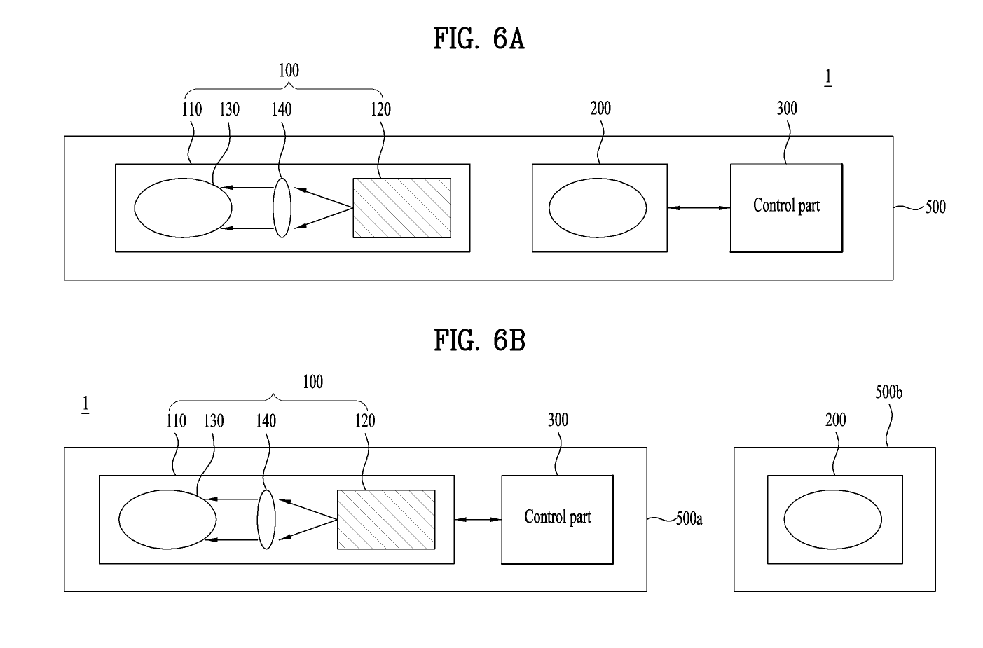

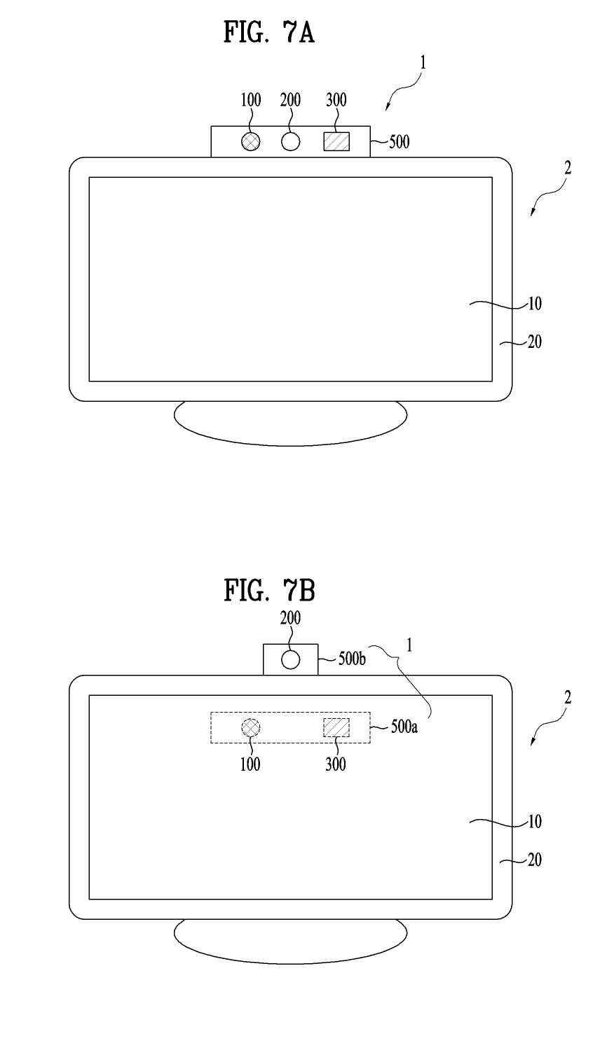

FIG. 6a and FIG. 6b illustrate plane views respectively showing positioning of a light irradiation part and a light receiving part, wherein FIG. 6a corresponds to an integrated module, and wherein FIG. 6b corresponds to a detachable module.

As shown in FIG. 6a and FIG. 6b, the depth image obtaining device according to the present invention may correspond to an integrated module having a light irradiation part (100) and a light receiving part (200) being positioned on a same substrate, or may correspond to a detachable module having each of a light irradiation part (100) and a light receiving part (200) positioned on a different substrate.

Herein, in the integrated module, as shown in FIG. 6a, a light irradiation part (100), a light receiving part (200), and a control part (300) may be positioned on a same substrate (500).

At this point, the light irradiation part (100) may be configured of a light source part (120) and a reflection part (130) and an optical member (140) being positioned on a substrate (110).

Additionally, the light receiving part (200) and the control part (300) may be formed on one side next to the light irradiation part (100).

Subsequently, as shown in FIG. 6b, a detachable module may include a first detachable module and a second detachable module, and, herein, the first detachable module may be configured of a light irradiation part (100) and a control part (300) being positioned on a first substrate (500a), and the second detachable module may be configured of a light receiving part (200) being positioned on a second substrate (500b).

Herein, the control part (300) may control the light irradiation part (100) and the light receiving part (200), and, herein, the control part (300) may control the light irradiation part (100) and the light receiving part (200) simultaneously, and, in some cases, the control part (300) may control the light irradiation part (100) and the light receiving part (200) at different time points.

As described above, the depth image obtaining device according to the present invention may be manufactured as an integrated module having the light irradiation part (100) and the light receiving part (200) being collectively positioned therein, and the depth image obtaining device according to the present invention may also be manufactured as a detachable module having the light irradiation part (100) and the light receiving part (200) separately positioned therein.

FIG. 7a and FIG. 7b respectively illustrate a depth image obtaining device being equipped to a display device.

As shown in FIG. 7a and FIG. 7b, a depth image obtaining device (1) according to the present invention may be applied to a display device (2).

Herein, the display device (2) may not only be applied to fixed terminals (or user equipments), such as digital TVs, desktop computers, digital signage, and so on, but may also be applied to mobile terminals (or user equipments).

Additionally, the depth image obtaining device (1) may correspond to an integrated module having the light irradiation part (100) and the light receiving part (200) being positioned on a same substrate, or the depth image obtaining device (1) may correspond to a detachable module having each of the light irradiation part (100) and the light receiving part (200) being positioned on different substrates.

More specifically, the integrated module may be configured of the light irradiation part (100) and the light receiving part (200) and the control part (300) being positioned on the same substrate (500).

As shown in FIG. 7a, the depth image obtaining device (1) of an integrated module may be mounted on a peripheral portion of the display device (2), and, in this case, the depth image obtaining device (1) may be partially exposed to the outside from the display device (2).

For example, the depth image obtaining device (1) of the integrated module may be mounted on a peripheral portion of a frame (20) excluding a display panel (10) of the display device (2).

Additionally, a detachable module may include a first detachable module and a second detachable module, and, herein, the first detachable module may be configured of a light irradiation part (100) and a control part (300) being positioned on a first substrate (500a), and the second detachable module may be configured of a light receiving part (200) being positioned on a second substrate (500b).

As shown in FIG. 7b, the depth image obtaining device (1) of a detachable module may be configured of a first detachable module being positioned inside the display device, wherein the first detachable module includes the light irradiation part (100) and the control part (300), and a second detachable module being mounted to be exposed to be outside from the display device, wherein the second detachable module includes the light receiving part (200).

For example, the first detachable module including the light irradiation part (100) and the control part (300) may be positioned behind the display panel (10) of the display device (2), and the second detachable module including the light receiving part (200) may be positioned on a peripheral portion of the frame (20) of the display device (2).

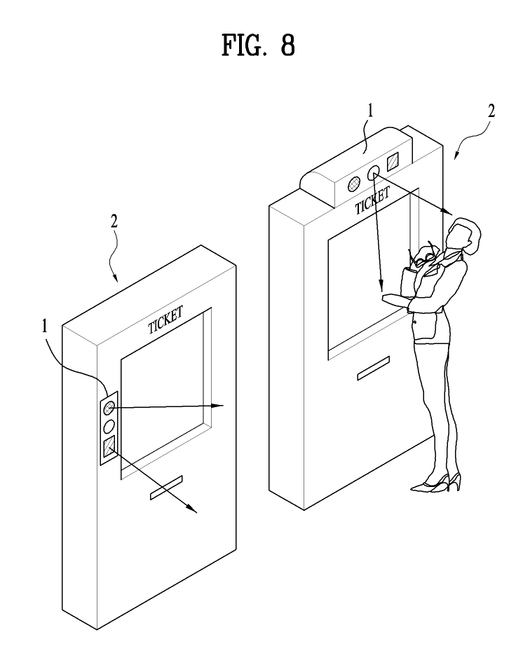

FIG. 8 illustrates a depth image obtaining device being applied to a display device having a large screen.

As shown in FIG. 8, the depth image obtaining device (1) according to the present invention may be applied to a display device (2) having a large screen.

For example, a display device (2) having a large screen may include a digital signage, and so on, and, herein, the user may obtain necessary information by touching the large screen of the display device (2) or by performing a gesture as a predetermined distance.

Herein, since the depth image obtaining device according to the present invention uses a high output light source without increasing the thickness and size of the device, the device may be realized in a compact size, and the depth image obtaining device may accurately obtain a depth image respective to the user being positioned at a remote location.

Accordingly, by accurately recognizing the gesture of the user, the display device being equipped with the depth image obtaining device according to the present invention may perform accurate functions and may deliver accurate information.

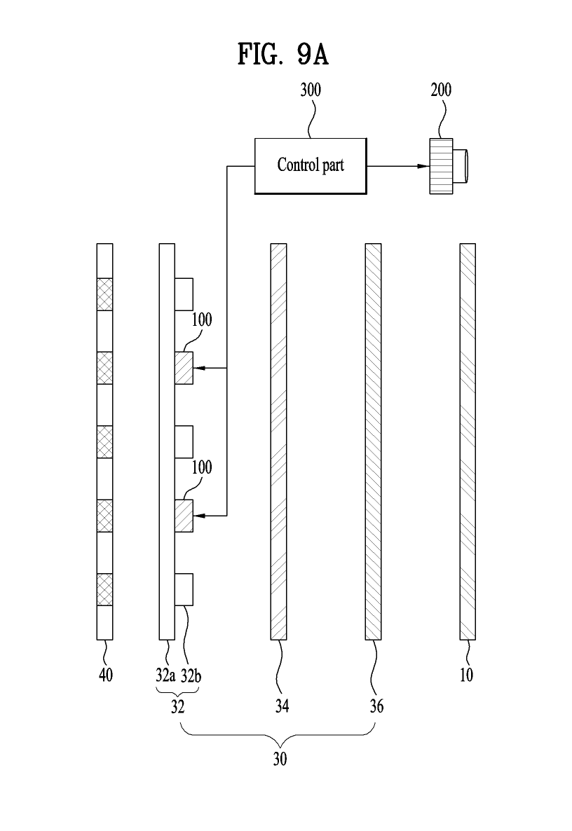

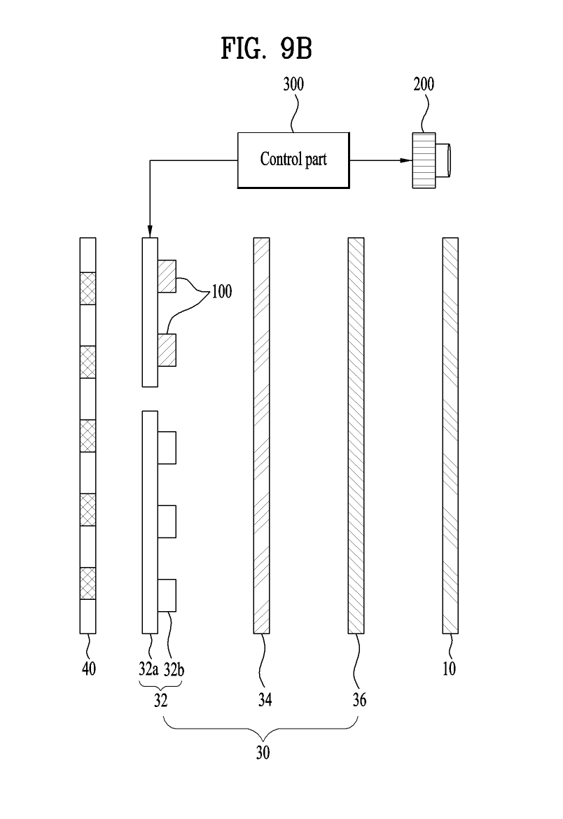

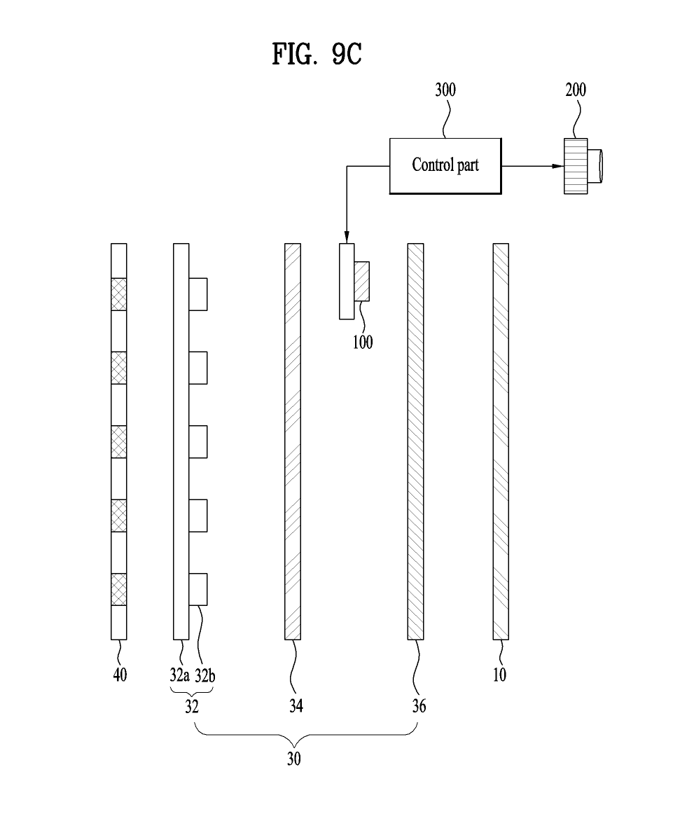

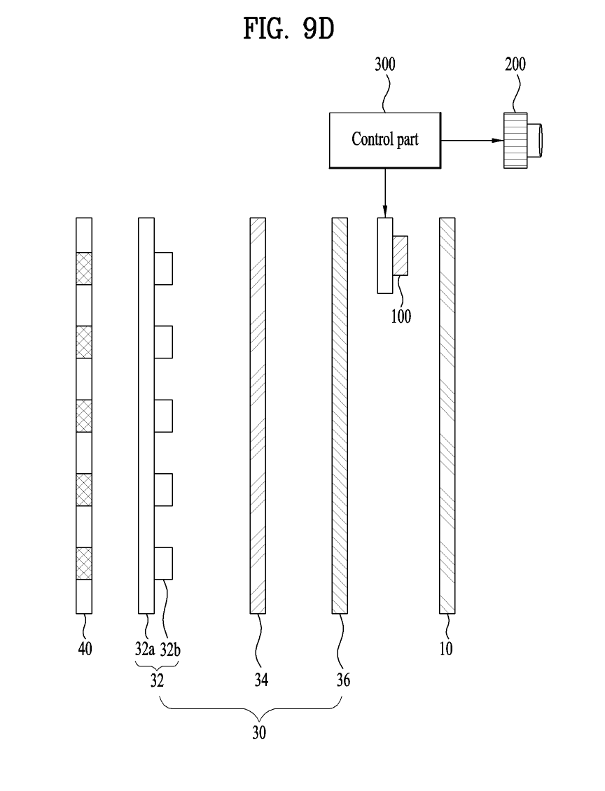

FIG. 9a to FIG. 9d respectively illustrate exploded views showing a display device using the depth image obtaining device according to the present invention.

As shown in FIG. 9a to FIG. 9d, the display device may include a depth image obtaining device including a light irradiation part (100), a light receiving part (200), and a control part (300), a display panel (10), and a backlight unit (30) irradiating light onto the display panel (10).

Herein, the light irradiation part (100) may be positioned inside the backlight unit (300), thereby being capable of irradiating light onto a predetermined subject, and the light receiving part (200) may be positioned on a peripheral portion of the display panel (10), thereby being capable of receiving light that is reflected from the subject, and the control part (300) may control the light irradiation part (100) and the light receiving part (200).

Additionally, the light irradiation part (100) may include a light source part emitting light in a first direction, and a reflection part reflecting the light emitted in the first direction into a second direction.

Moreover, the backlight unit (30) may include a light source module (32) including a substrate (32a), and multiple light sources (32b) being positioned on the substrate (32a), a dispersion plate (34) being positioned over the light source module (32), and an optical member (36) being positioned over the dispersion plate (34).

Subsequently, a heat radiation plate (40) may be positioned below the substrate (32a) of the light source module (32).

At this point, the light irradiation part (100) may be positioned inside the light source module (32), or the light irradiation part (100) may be positioned between the light source module (32) and the dispersion plate (34), or the light irradiation part (100) may be positioned between the dispersion plate (34) and the optical member (36).

As shown in FIG. 9a, the light irradiation part (100) may be positioned between the light sources (32b) of the light source module (32).

Herein, the light irradiation part (100) and the light source (32b) may be positioned on the same substrate (32a).

More specifically, the light source of the light irradiation part (100) and the light source (32b) of the display device may be positioned on the same substrate (32a), so as to be inter-mixed with one another.

At this point, by positioning the heat radiation plate (40) under the substrate (32a) of the light source module (32), heat radiation of the light irradiation part (100) of the depth image obtaining device and heat radiation of the light source (32b) of the display device may be simultaneously used through a single heat radiation plate (40).

Additionally, the light source (32b) of the display device may correspond to a white light source, and the light source of the light irradiation part (100) may correspond to an infrared light source.

Accordingly, a color cut filter, which is configured to remove (or eliminate) color waves, may be additionally positioned in the light source of the light irradiation part (100), wherein the light source corresponds to an infrared light source.

As shown in FIG. 9b, the light irradiation part (100) may be positioned on one side next to the light source module (32), so as to be spaced apart from the light source module (32) at a predetermined distance.

More specifically, the substrate having the light irradiation part (100) placed thereon may be positioned on one side next to the substrate (32a) having the light source module (100) placed thereon, so as to be spaced apart from the corresponding substrate (32a) at a predetermined distance.

In some cases, the light irradiation part (100) may be positioned between the light source module (32) and the dispersion plate (34).

In another case, as shown in FIG. 9c, the light irradiation part (100) may also be positioned between the dispersion plate (34) and the optical member (36).

In yet another case, as shown in FIG. 9d, the light irradiation part (100) may also be positioned between the optical member (36) and the display panel (10).

As described above, by being placed on diverse positions within the display device, the light irradiation part (100) of the depth image obtaining device may be capable of accurately obtaining a depth image respective to the user being positioned at a remote location.

Accordingly, by accurately recognizing the gestures of the user, the display device using the depth image obtaining device according to the present invention may perform accurate functions and may deliver accurate information.

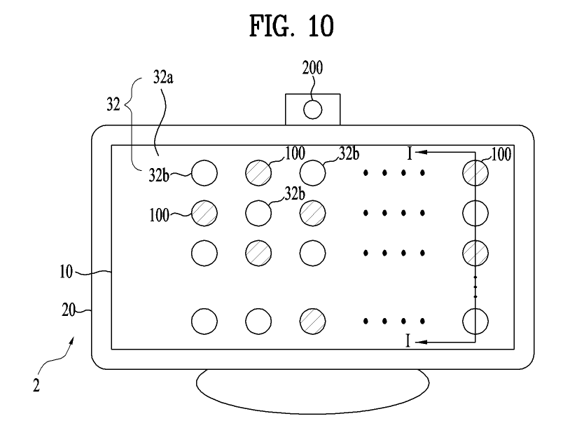

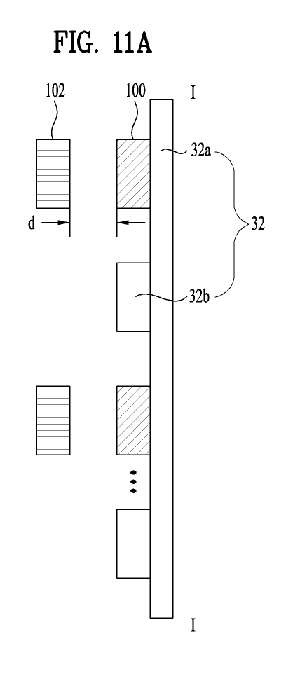

FIG. 10 illustrates a positioning of a light irradiation part being applied to a backlight unit of the display device according to the present invention.

As shown in FIG. 10, the display device (2) may not only be applied to fixed terminals (or user equipments), such as digital TVs, desktop computers, digital signage, and so on, but may also be applied to mobile terminals (or user equipments).

Herein, a light source module (32) of the backlight unit is positioned behind a display panel (10) of the display device (2).

At this point, the light source module (32) of the backlight unit may include a substrate (32a) and multiple light sources (32b) aligned on the substrate (32a).

Additionally, the light irradiation part (100) of the depth image obtaining device may be positioned between the light sources (32b) being adjacent to one another.

Herein, the light irradiation part (100) of the depth image obtaining device and the light source (32b) of the backlight unit may be positioned on the same substrate (32a) and may be alternately positioned along a row direction (or horizontal direction) or a column direction (or a vertical direction).

In some cases, although a ratio between a number of light irradiation parts (100) of the depth image obtaining device and a number of light sources (32b) of the backlight unit may correspond to 1:1˜1:50, the present invention will not be limited only to this.

In another case, among the overall substrate (32a) area of the backlight unit, the light irradiation part (100) of the depth image obtaining device may be positioned in an area that is adjacent to a light receiving part (200) of the depth image obtaining device.

This is because error calibration may be minimized, since there is little error in calculating a distance from the subject.

Furthermore, the light receiving part (200) of the depth image obtaining device may be positioned on a peripheral portion of a frame (20) of the display device (2).

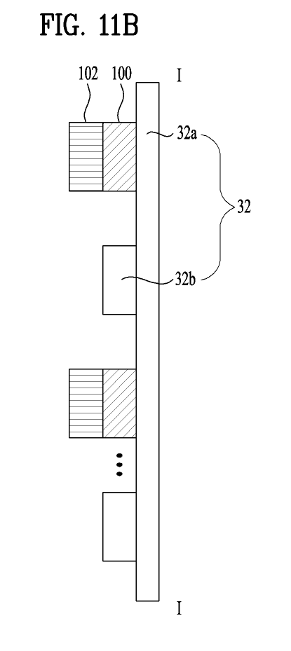

FIG. 11a and FIG. 11b illustrate cross-sectional views taken along line I-I of FIG. 10.

As shown in FIG. 11a and FIG. 11b, the light source module (32) of the backlight unit may be configured of multiple light sources (32b) being positioned on the substrate (32a) and the light irradiation part (100) of the depth image obtaining device being positioned between the light sources (32b), which are adjacent to one another.

Herein, a color cut filter (102) may be positioned over the light irradiation part (100) of the depth image obtaining device.

At this point, the color cut filter (102) may be positioned along a light emitting direction of the light irradiation part (100).

Additionally, as shown in FIG. 11a, the color cut filter (102) may be positioned to be spaced apart from the light irradiation part (100) at a predetermined distance d.

Herein, a distance between the color cut filter (102) and the light irradiation part (100) may be decided (or determined) based upon a distance that can fully (or completely) cut out (or block) the light being emitted from the light irradiation part (100).

More specifically, this is because, if the distance between the color cut filter (102) and the light irradiation part (100) is excessively large, the light being emitted from the light irradiation part (100) may be dispersed, which may prevent the light from being fully blocked (or cut out).

In some cases, as shown in FIG. 11b, the color cut filter (102) may also be positioned on the light irradiation part (100), so as to contact the light irradiation part (100).

Herein, in case the light being emitted from the light irradiation part (100) is a light corresponding to an infrared wavelength, the color cut filter (102) may remove (or eliminate) the light corresponding to colors that are shown (or appear) in the light rays of infrared wavelengths.

Accordingly, light being emitted from the light source (32b) of the backlight unit and light being filtered by the color cut filter (102) may both correspond to white light.

In case there is no color cut filter (102), due to the infrared light being emitted from the light irradiation part of the depth image obtaining device, degradation may occur in an image in the display panel (10) of the display panel.

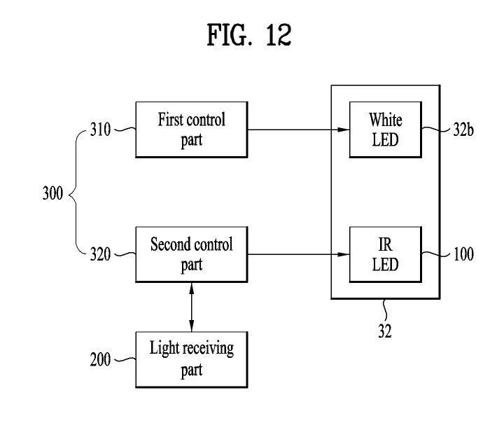

FIG. 12 illustrates a block view showing a structure of a control part controlling the backlight unit of the display device according to the present invention.

As shown in FIG. 12, in the backlight unit of the display device, the light source module (32) may include a light source of the light irradiation part (100) of the depth image obtaining device and a light source (32b) of the backlight unit.

Moreover, the control part (300) includes a first control part (310) and a second control part (320), wherein the first control part (310) may control the light source (32b) of the backlight unit, and wherein the second control part (320) may control the light source of the light irradiation part (100) and the light receiving part (200).

Herein, the first control part (310) may control the light source (32b) of the backlight unit in accordance with a received image signal, and the second control part (320) may drive (or operate) the light irradiation part (100) and the light receiving part (200) at the same time in order to obtain a depth image, and, in some cases, the second control part (320) may drive (or operate) the light irradiation part (100) and the light receiving part (200) at different time points.

Accordingly, by controlling the light source module of the backlight unit as well as the light irradiation part of the depth image obtaining device, which is included in the display device, the display device according to the present invention may perform accurate functions and may deliver accurate information.

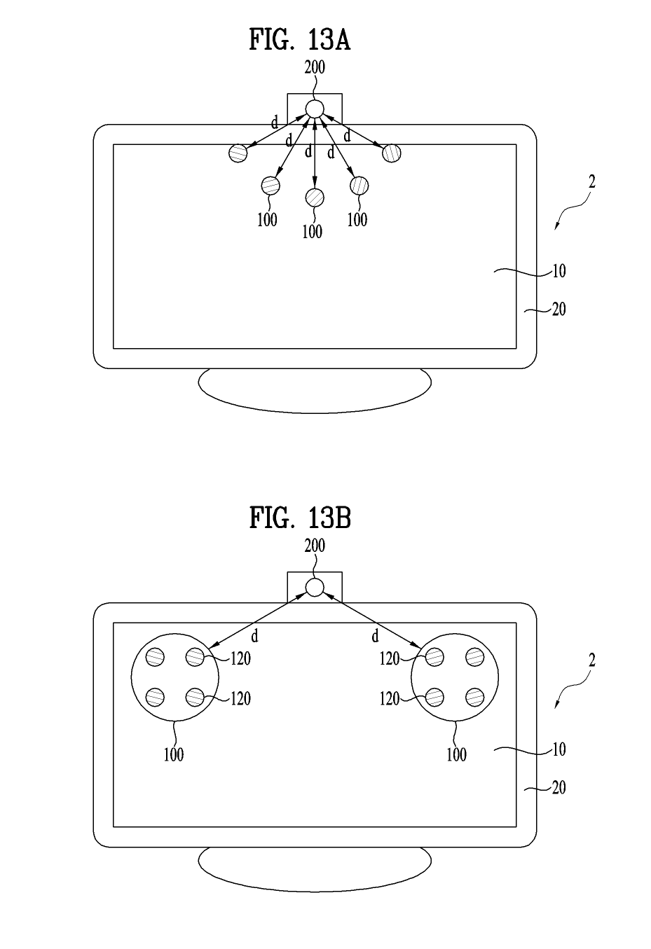

FIG. 13a and FIG. 13b respectively illustrate alignments of the light irradiation part being positioned in the backlight unit of the display device according to the present invention.

As shown in FIG. 13a and FIG. 13b, the light irradiation part (100) of the depth image obtaining device may be positioned behind the display panel (10) of the display device (2).

And, the light receiving part (200) of the depth image obtaining device may be positioned on a peripheral portion of the frame (20) of the display device (2).

Herein, the light irradiation part (100) of the depth image obtaining device may be positioned to be neighboring the light receiving part (200) of the depth image obtaining device.

As shown in FIG. 13a, in case the light irradiation part (100) is positioned in the form of multiple separate modules, the multiple separate modules may be positioned so that each of multiple separate modules can be spaced apart from the light receiving part (200) at equal distances.

For example, when the light irradiation part (100) includes 3 light irradiation parts being the first, second, and third light irradiation parts, the first light irradiation part and the light receiving part (200) may be positioned to be spaced apart from one another at a first distance d1, and the second light irradiation part and the light receiving part (200) may be positioned to be spaced apart from one another at a second distance d2, and the third light irradiation part and the light receiving part (200) may be positioned to be spaced apart from one another at a third distance d3.

Herein, the first distance d1, the second distance d2, and the third distance d3 may all be equal to one another.

In some cases, as shown in FIG. 13b, when the light irradiation part (100) is positioned in the form of multiple group modules including multiple separate modules, the multiple separate groups may be positioned so that each of the multiple separate groups can be spaced apart from the light receiving part (200) at equal distances.

For example, when the light irradiation part (100) is configured of a first group including 4 light irradiation parts being first, second, third, and fourth light irradiation parts, and a second group including 4 light irradiation parts being fifth, sixth, seventh, and eighth light irradiation parts, the first group and the light receiving part (200) may be positioned to be spaced apart from one another at a fourth distance d4, and the second group and the light receiving part (200) may be positioned to be spaced apart from one another at a fifth distance d5.

Herein, the fourth distance d4 and the fifth distance d5 may be equal to one another.

In some cases, the light irradiation part (100) may include multiple light source parts (120).

As described above, the distance between the light irradiation part (100) and the light receiving part (200) is set to be consistent because, in case the distances between the light irradiation part (100) and the light receiving part (200) are different, it is difficult to accurately calculate the distance between the light irradiation part (100) and the subject due to on/off time differences between the light irradiation parts (100).

Accordingly, if the distances between the light irradiation part (100) and the light receiving part (200) are set to be consistent, little error occurs in calculating the distance from the subject, thereby minimizing error calibration.

Furthermore, the above-described distance between the light irradiation part (100) and the light receiving part (200) may correspond to a distance between the light emitting surface of the light irradiation part (100) and the light receiving surface of the light receiving part (200).

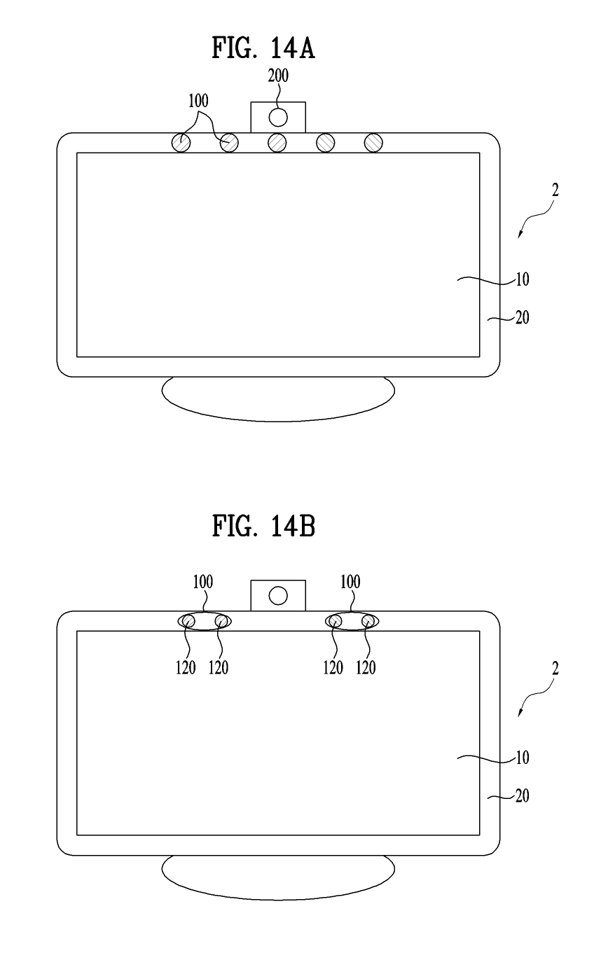

FIG. 14a and FIG. 14b respectively illustrate alignments of the light irradiation part being positioned in a frame of a display device.

As shown in FIG. 14a and FIG. 14b, a frame (20) is positioned on the peripheral portion of the display panel (10) of the display device (2), and, herein, the frame (20) may include all areas excluding an active area, wherein images are displayed.

Herein, the light irradiation part (100) of the depth image obtaining device may be positioned in the frame (20) area of the display device (2).

Additionally, the light receiving part (200) of the depth image obtaining device may be positioned on the peripheral portion of a frame (20) of the display device (2).

Herein, the light irradiation part (100) of the depth image obtaining device may be positioned on a frame (20) area most approximate to the light receiving part (200) of the depth image obtaining device.

This is because, if the distance between the light irradiation part (100) and the light receiving part (200) is small (or short), error calibration may be minimized, since there is little error in calculating a distance from the subject.

As shown in FIG. 14a, in case the light irradiation part (100) is positioned in the form of multiple separate modules, the multiple separate modules may be positioned along the frame (20) of the display device (2) at constant intervals.

Herein, the light irradiation part (100) may be positioned in the frame (20) area of the display device (2) being adjacent to the light receiving part (200).

In some cases, as shown in FIG. 14b, when the light irradiation part (100) is positioned in the form of multiple group modules including multiple separate modules, the multiple separate groups may be positioned along the frame (20) of the display device (2) at constant intervals.

For example, when the light irradiation part (100) is configured of a first group including 4 light irradiation parts being first, second, third, and fourth light irradiation parts, and a second group including 4 light irradiation parts being fifth, sixth, seventh, and eighth light irradiation parts, the first group and the second group may be positioned in the frame (20) area of the display device (2) being adjacent to the light receiving part (200).

In some cases, the light irradiation part (100) may also include multiple light source parts (120).

As described above, the depth image obtaining device and the display device using the same according to the present invention may resolve the eye-safety problem without increasing the thickness and size of the lighting module, thereby being capable of accurately obtaining a depth image respective to the user being positioned at a remote location.

### MODE FOR CARRYING OUT THE PRESENT INVENTION

As described above, instead of having the configuration and method of the above-described exemplary embodiments be applied with limitations (or restrictions), the depth image obtaining device and the display device using the same according to the present invention may also be configured as optional combination of the above-described exemplary embodiments fully or in part.

Additionally, although drawings and detailed description of the preferred embodiments of the present invention are provided above, the present invention will not be limited only to the specific exemplary embodiment that is described above. And, therefore, it will be apparent that diverse variations and modifications may be realized on the present invention by anyone skilled in the art without departing from the principles of the present invention as claimed in the scope of the appended claims of the present invention. And, such variations and modifications shall not be individually or separately understood from the technical scope and spirit of the present invention.

### INDUSTRIAL APPLICABILITY

The present invention relates to a depth image obtaining device, which is capable of obtaining depth image of a subject being positioned at a remote location, and a display device using the same. Therefore, the present invention has industrial applicability.

What is claimed is:

1. A depth image obtaining device, comprising:
a light irradiation part for irradiating light onto a predetermined subject;
a light receiving part for receiving light reflected from the subject; and
a control part for controlling the light irradiation part and the light receiving part,
wherein the light irradiation part comprises:
a light source part for emitting light in a first direction, and
a reflection part for reflecting the light emitted in the first direction into a second direction.

2. The device of claim 1, wherein a central axis of the light being emitted in the first direction and a central axis of the light being reflected along the second direction are perpendicular to one another.

3. The device of claim 1, wherein the light source part corresponds to at least one of a laser diode and a VCSEL (Vertical Cavity Surface Emitting Laser).

4. The device of claim 1, wherein the reflection part corresponds to a parabolic front coated mirror.

5. The device of claim 1, wherein the light source part and the reflection part are positioned on a same substrate, and wherein the light source part and the reflection part are serially aligned.

6. The device of claim 1, wherein the light irradiation part further comprises:
an optical member positioned between the light source part and the reflection part for providing the light emitted from the light source part as a collimated light.

7. The device of claim 1, wherein the light irradiation part and the light receiving part are configured as an integrated module by being positioned on a same substrate.

8. The device of claim 7, wherein the integrated module comprising the light irradiation part and the light receiving part is mounted on a display device, and wherein the integrated module is exposed outside from the display device.

9. The device of claim 1, wherein the light irradiation part is positioned on a first substrate so as to be configured as a first detachable module, and wherein the light receiving part is positioned on a second substrate so as to be configured as a second detachable module.

10. The device of claim 9, wherein the first detachable module comprising the light irradiation part and the second detachable module comprising the light receiving part are mounted on a display device, wherein the first detachable module is positioned inside the display device, and wherein the second detachable module is exposed outside from the display device.

11. The device of claim 10, wherein the first detachable module is positioned behind a display panel of the display device.

12. As a display device using a depth image obtaining device comprises a light irradiation part and a light receiving part, the display device comprises:
a display panel;
a backlight unit for emitting light onto the display panel;
a light irradiation part positioned inside the backlight unit for irradiating light onto a predetermined subject;
a light receiving part positioned on a peripheral portion of the display panel for receiving light reflected from the subject; and
a control part for controlling the light irradiation part and the light receiving part,
wherein the light irradiation part comprises:
a light source part for emitting light in a first direction, and
a reflection part for reflecting the light emitted in the first direction into a second direction.

13. The device of claim 12, wherein the backlight unit comprises:
a light source module comprising a substrate and multiple light sources being positioned on the substrate;
a dispersion plate positioned over the light source module; and
an optical member positioned over the dispersion plate,
wherein the light irradiation part is positioned in at least any one of a location inside the light source module, a location between the light source module and the dispersion plate, and a location between the dispersion plate and the optical member.

14. The device of claim 13, wherein the light irradiation part is positioned between light sources of the light source module.

15. The device of claim 14, wherein the light irradiation part and the light source are positioned on a same substrate.

16. The device of claim 13, wherein a heat radiation plate is positioned under the substrate of the light source module.

17. The device of claim 13, wherein the light irradiation part is positioned on one side next to the light source module, so as to be spaced apart from the light source module at a predetermined distance.

18. The device of claim 12, wherein a color cut filter is positioned over the light irradiation part.

19. The device of claim 12, wherein the light irradiation part is positioned as multiple separate modules, or wherein the light irradiation part is positioned as multiple group modules comprising multiple separate modules,
wherein the multiple separate modules are positioned to be spaced apart from the light receiving part at equal distances, and
wherein the multiple separate groups are positioned to be spaced apart from the light receiving part at equal distances.

20. The device of claim 12, wherein the light irradiation part is positioned on a peripheral portion of the display panel so as to be adjacent to the light receiving part.
